(19) United States
(12) Patent Application Publication
(10) Pub. No.: US 2015/0014658 A1
(43) Pub. Date: Jan. 15, 2015

(54) ORGANIC LIGHT EMITTING DIODE DISPLAY AND METHOD FOR MANUFACTURING THE SAME

(71) Applicant: Samsung Display Co., Ltd., Yongin-City (KR)

(72) Inventors: Ji Young CHOUNG, Yongin-City (KR); Hyun Sung BANG, Bucheon-City (KR); Joon Gu LEE, Seoul (KR); Jin Baek CHOI, Anyang-City (KR); Yeon Hwa LEE, Yongin-City (KR)

(21) Appl. No.: 14/282,154

(22) Filed: May 20, 2014

(30) Foreign Application Priority Data
Jul. 15, 2013 (KR) 10-2013-0083129

(51) Int. Cl. H01L 51/52; H01L 51/56

(52) U.S. Cl. CPC H01L 51/5203; H01L 51/56
USPC 257/40; 438/29

(57) ABSTRACT

Disclosed are an organic light emitting diode display and a method for manufacturing the same. The organic light emitting diode display includes: a driving switching element; a pixel electrode connected with the driving switching element; an auxiliary electrode separated from the pixel electrode and positioned in a same layer as the pixel electrode; an organic common layer positioned on the pixel electrode and the auxiliary electrode and including a contact hole positioned on the auxiliary electrode; and a common electrode positioned on the organic common layer and connected with the auxiliary electrode through the contact hole; and the auxiliary electrode includes a light absorbing layer.

### CLAIM OF PRIORITY

This application makes reference to, incorporates the same herein, and claims all benefits accruing under 35 U.S.C. §119 from an application for ORGANIC LIGHT EMITTING DIODE DISPLAY AND METHOD FOR MANUFACTURING THE SAME earlier filed in the Korean Intellectual Property Office on 15 Jul. 2013 and there duly assigned Serial No. 10-2013-0083129.

### BACKGROUND OF THE INVENTION

1. Field of the Invention

The present invention relates to an organic light emitting diode display and a method for manufacturing the same.

2. Description of the Related Art

A display device, such as a liquid crystal display (LCD), an organic light emitting diode display (OLED display), and an electrophoretic display, includes a field generating electrode and an electro-optical active layer. The liquid crystal display may include a liquid crystal layer as the electro-optical active layer, and the organic light emitting diode display may include an organic light emitting layer as the electro-optical active layer, and the electrophoretic display may include charged particles. The field generating electrode is connected to a switching element such as a thin film transistor to receive a data signal, and the electro-optical active layer converts the data signal to an optical signal to display an image.

Since the organic light emitting diode display (OLED display) among the display devices does not require a separate light source as a self light emitting type, the organic light emitting diode display is advantageous in terms of power consumption, and is excellent in a response speed, a viewing angle, and a contrast ratio.

The organic light emitting diode display includes a plurality of pixels such as a red pixel, a blue pixel, a green pixel, and a white pixel, and may express a full color by combining the pixels. Each pixel includes an organic light emitting element and a plurality of thin film transistors for driving the organic light emitting element.

The light emitting element of the organic light emitting diode display includes a pixel electrode, a common electrode, and a light emitting layer positioned between the pixel electrode and the common electrode. One of the pixel electrode and the common electrode is an anode, and the other is a cathode. An electron injected from the cathode and a hole injected from the anode are coupled with each other in the light emitting layer to form an exciton, and the exciton discharges energy to emit light. The common electrode is formed throughout the plurality of pixels and may transfer a predetermined common voltage.

The organic light emitting diode display may be divided into a bottom emission type in which light is emitted to the bottom of a substrate and a top emission type in which light is emitted to the top of the substrate. In the case of the top emission type organic light emitting diode display, the common electrode is made of a transparent conductive material.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an organic light emitting diode display and a method for manufacturing the same having advantages of preventing a display stain and improving display quality by uniformizing a common voltage transferred by a common electrode.

Further, the present invention has been made in an effort to provide an organic light emitting diode display and a method for manufacturing the same having advantages of reducing manufacturing costs and manufacturing times of the organic light emitting diode display and simplifying a manufacturing process.

In addition, the present invention has been made in an effort to provide an organic light emitting diode display and a method for manufacturing the same having advantages of preventing an auxiliary electrode from being damaged in a manufacturing process of the organic light emitting diode display including the auxiliary electrode.

An exemplary embodiment of the present invention provides an organic light emitting diode display, may including: a driving switching element; a pixel electrode connected with the driving switching element; an auxiliary electrode separated from the pixel electrode and positioned in a same layer as the pixel electrode; an organic common layer positioned on the pixel electrode and the auxiliary electrode and including a contact hole positioned on the auxiliary electrode; and a common electrode positioned on the organic common layer and connected with the auxiliary electrode through the contact hole; and the auxiliary electrode may include a light absorbing layer.

The light absorbing layer may have a light absorbing ratio of approximately 70% or more.

The light absorbing layer may include at least one metal including molybdenum (Mo), chromium (Cr), tungsten (W), and nickel (Ni).

The pixel electrode may include the light absorbing layer.

The auxiliary electrode and the pixel electrode each may include a lower layer, the light absorbing layer, a reflective layer, and an upper layer which are sequentially deposited from a bottom.

The auxiliary electrode and the pixel electrode each may include the light absorbing layer, a lower layer, a reflective layer, and an upper layer which are sequentially disposed from a bottom.

The pixel electrode may not include the light absorbing layer.

The auxiliary electrode may include a lower layer, a reflective layer, an upper layer, and the light absorbing layer which are sequentially disposed from a bottom, and the pixel electrode may include the lower layer, the reflective layer, and the upper layer which are sequentially disposed from the bottom.

The auxiliary electrode may include the light absorbing layer, a lower layer, a reflective layer, and an upper layer which are sequentially disposed from a bottom, and the pixel electrode may include the lower layer, the reflective layer, and the upper layer which are sequentially disposed from the bottom.

Another exemplary embodiment of the present invention provides a method for manufacturing an organic light emitting diode display, the method may including: forming a pixel electrode and an auxiliary electrode each including a light absorbing layer on a substrate; forming an organic common layer on the pixel electrode and the auxiliary electrode; locating a first optical mask below the substrate, the first optical mask including a light transmitting portion corresponding to the auxiliary electrode and a non-light transmitting portion corresponding to the pixel electrode; and removing a portion of the organic common layer positioned on the auxiliary electrode by irradiating light through the first optical mask.

The forming of the pixel electrode and the auxiliary electrode may include light exposing through a second optical mask.

The forming of the pixel electrode and the auxiliary electrode may include sequentially depositing a lower layer, a light absorbing layer, a reflective layer, and an upper layer on the substrate and then patterning the deposited layers by using the second optical mask.

The forming of the pixel electrode and the auxiliary electrode may include sequentially depositing a light absorbing layer, a lower layer, a reflective layer, and an upper layer on the substrate and then patterning the deposited layers by using the second optical mask.

The light absorbing layer may include at least one metal including molybdenum (Mo), chromium (Cr), tungsten (W), and nickel (Ni).

Yet another exemplary embodiment of the present invention provides a method for manufacturing an organic light emitting diode display, the method may including: forming a pixel electrode, and an auxiliary electrode including a light absorbing layer on a substrate; forming an organic common layer on the pixel electrode and the auxiliary electrode; and removing a portion of the organic common layer positioned on the auxiliary electrode by irradiating light to the auxiliary electrode.

The forming of the pixel electrode and the auxiliary electrode may include light exposing using two or more optical masks.

The forming of the pixel electrode and the auxiliary electrode may include sequentially depositing and patterning a lower layer, a reflective layer, and an upper layer on the substrate to form the pixel electrode and a part of the auxiliary electrode, and depositing and patterning a light absorbing layer on the part of the auxiliary electrode to form the auxiliary electrode.

The removing of the portion of the organic common layer positioned on the auxiliary electrode may include irradiating light from a side above the substrate.

The forming of the pixel electrode and the auxiliary electrode may include depositing and patterning a light absorbing layer on the substrate to forming a part of the auxiliary electrode, and sequentially depositing and patterning a lower layer, a reflective layer, and an upper layer on the substrate and the light absorbing layer to form the pixel electrode and the auxiliary electrode.

The removing of the portion of the organic common layer positioned on the auxiliary electrode may include irradiating light from a side below the substrate.

According to the exemplary embodiments of the present invention, it is possible to prevent a display stain and improve display quality by uniformizing a common voltage transferred by a common electrode. Further, it is possible to reduce manufacturing costs and manufacturing times of the organic light emitting diode display and simplify a manufacturing process, and prevent an auxiliary electrode from being damaged in a manufacturing process of the organic light emitting diode display including the auxiliary electrode.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an equivalent circuit diagram of one pixel of an organic light emitting diode display according to an exemplary embodiment of the present invention.

FIG. 2 is a layout view of one pixel of the organic light emitting diode display according to the exemplary embodiment of the present invention.

FIG. 3 is a cross-sectional view of the organic light emitting diode display of FIG. 2 taken along line III-III.

FIGS. 4 and 5 are layout views of a pixel electrode and an auxiliary electrode of the organic light emitting diode display according to the exemplary embodiment of the present invention, respectively.

FIGS. 6 to 9 are cross-sectional views enlarging a portion P of the organic light emitting diode display illustrated in FIG. 3, respectively.

FIG. 10 is a graph illustrating light absorbing ratio of a light absorbing layer of the organic light emitting diode display according to an exemplary embodiment of the present invention.

FIG. 11 is a cross-sectional view in one step of a manufacturing process of the organic light emitting diode display according to an exemplary embodiment of the present invention.

FIGS. 12 to 17 are cross-sectional views illustrating respective steps of a manufacturing method of the organic light emitting diode display according to an exemplary embodiment of the present invention in sequence, and cross-sectional views illustrating steps after the manufacturing step illustrated in FIG. 11.

FIGS. 18 to 24 are cross-sectional views illustrating respective steps of a manufacturing method of the organic light emitting diode display according to an exemplary embodiment of the present invention in sequence, and cross-sectional views illustrating steps after the manufacturing step illustrated in FIG. 11.

FIGS. 25 to 31 are cross-sectional views illustrating respective steps of a manufacturing method of the organic light emitting diode display according to an exemplary embodiment of the present invention in sequence, and cross-sectional views illustrating steps after the manufacturing step illustrated in FIG. 11.

FIGS. 32 to 37 are cross-sectional views illustrating respective steps of a manufacturing method of the organic light emitting diode display according to an exemplary embodiment of the present invention in sequence, and cross-sectional views illustrating steps after the manufacturing step illustrated in FIG. 11.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

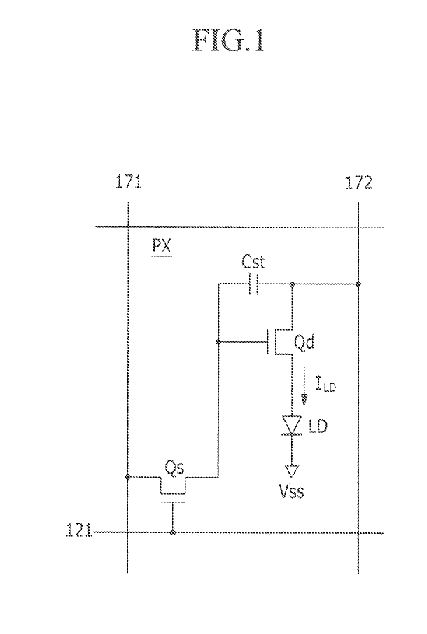

First, an organic light emitting diode display according to an exemplary embodiment of the present invention will be described with reference to FIG. 1.

FIG. 1 is an equivalent circuit diagram of one pixel of an organic light emitting diode display according to an exemplary embodiment of the present invention.

Referring to FIG. 1, the organic light emitting diode display according to the exemplary embodiment of the present invention may include a plurality of signal lines 121, 171, and 172 and a plurality of pixels PX connected thereto and arranged substantially in a matrix form.

The signal lines may include a plurality of scanning signal lines 121 transferring gate signals (or scanning signals), a plurality of data lines 171 transferring data signals, and a plurality of driving voltage lines 172 transferring driving voltages. The scanning signal lines 121 may extend substantially in a row direction and are substantially parallel to each other, and the data lines 171 and the driving voltage lines 172 may extend substantially in a column direction and may be substantially parallel to each other, respectively. The driving voltage lines 172 may extend substantially in the column direction, but contrary to this, may extend in a row direction or be formed in a net shape.

Each pixel PX may include a switching element which may be a switching transistor Qs, a driving switching element which may be a driving transistor Qd, a storage capacitor Cst, and an organic light emitting element LD.

The switching transistor Qs may have a control terminal, an input terminal, and an output terminal, and the control terminal may be connected to the scanning signal line 121, the input terminal may be connected to the data line 171, and the output terminal may be connected to the driving transistor Qd. The switching transistor Qs may transfer a data signal received from the data line 171 to the driving transistor Qd in response to a scanning signal received from the scanning signal line 121.

The driving transistor Qd may also have a control terminal, an input terminal, and an output terminal, and the control terminal may be connected to the switching transistor Qs, the input terminal may be connected to the driving voltage line 172, and the output terminal may be connected to the organic light emitting element LD. The driving transistor Qd may discharge an output current I_{LD} of which a magnitude varies according to a voltage applied between the control terminal and the output terminal.

The storage capacitor Cst may be connected between the control terminal and the input terminal of the driving transistor Qd. The storage capacitor Cst may charge a data signal applied to the control terminal of the driving transistor Qd and maintains the charged data signal even after the switching transistor Qs is turned off.

The organic light emitting element LD, for example, as an organic light emitting diode (OLED), may include an anode connected to the output terminal of the driving transistor Qd and a cathode connected to a common voltage Vss. The organic light emitting element LD may emit light by varying an intensity according to the output current I_{LD} of the driving transistor Qd to display an image. The organic light emitting element LD may include an organic material which uniquely emits any one or one or more light of the primary colors such as three primary colors of red, green, and blue, or an organic material which emits white, and the organic light emitting diode display may display a desired image by a spatial sum of the colors.

The switching transistor Qs and the driving transistor Qd may be n-channel field effect transistors (FET), but at least one thereof may be a p-channel field effect transistor. Further, a connection relationship of the switching transistors Qs and the driving transistor Qd, the storage capacitor Cst, and the organic light emitting element LD may be changed.

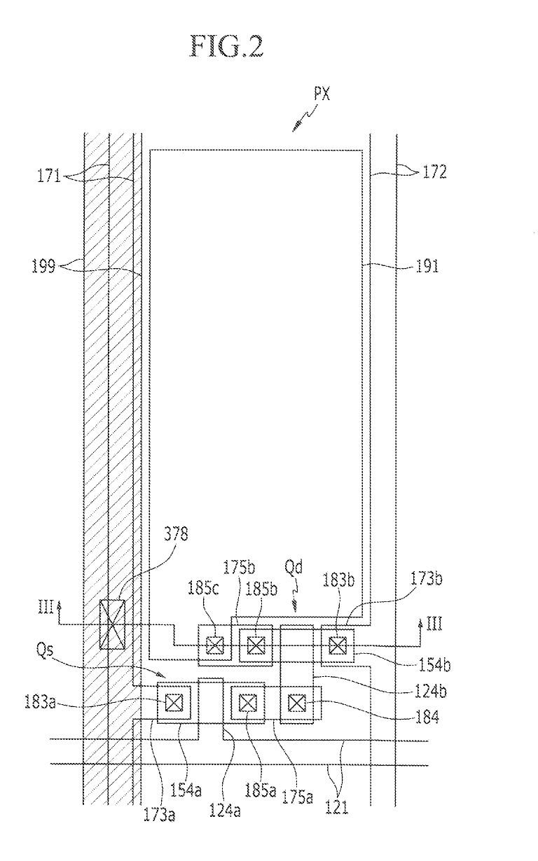

Then, a detailed structure of the organic light emitting diode display illustrated in FIG. 1 will be described in detail with reference to FIGS. 2 to 10.

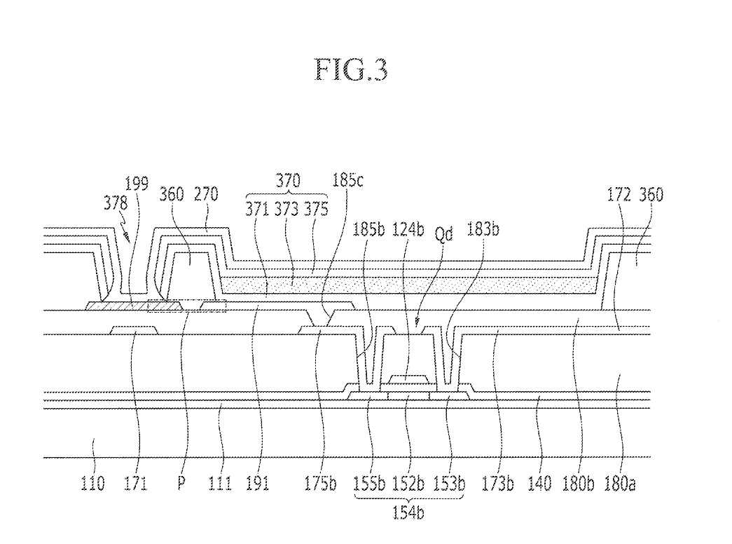

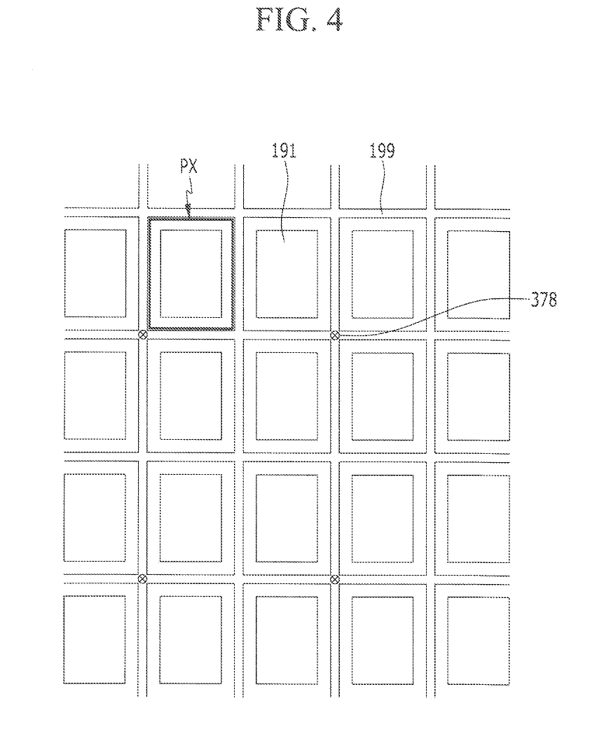

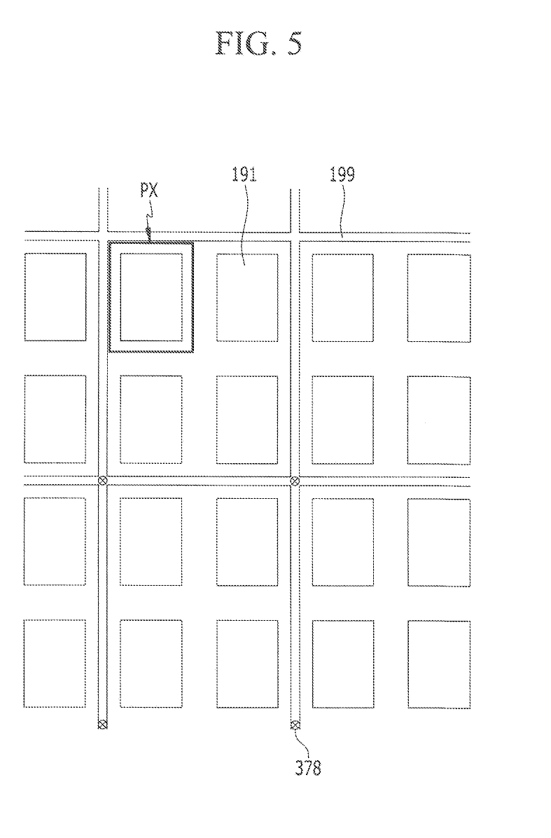

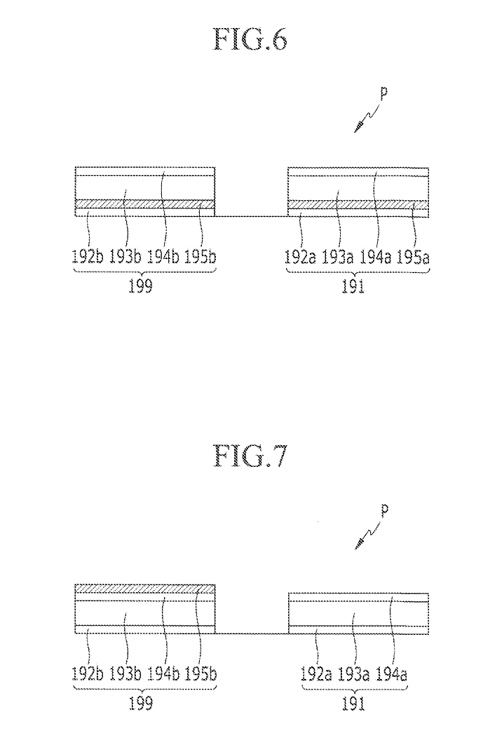

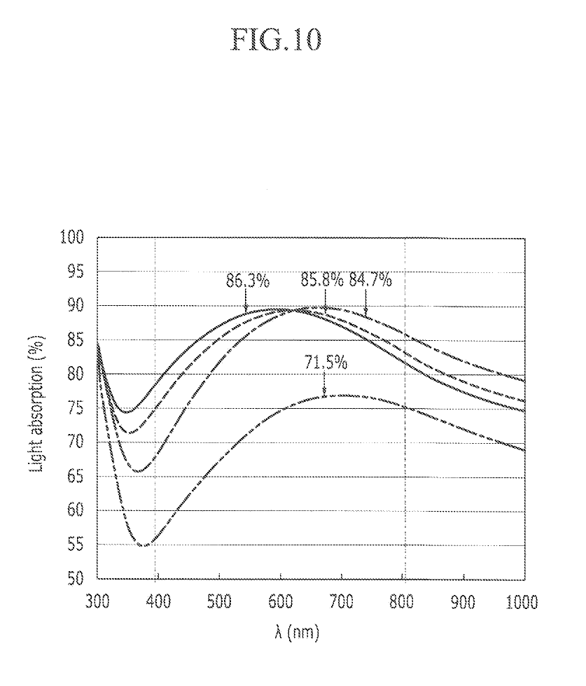

FIG. 2 is a layout view of one pixel of the organic light emitting diode display of FIG. 1 according to the exemplary embodiment of the present invention, FIG. 3 is a cross-sectional view of the layout view of one pixel of the organic light emitting diode display of FIG. 2 taken along line III-III, FIGS. 4 and 5 are layout views of a pixel electrode and an auxiliary electrode of the organic light emitting diode display according to the exemplary embodiment of the present invention, respectively, FIGS. 6 to 9 are cross-sectional views enlarging a portion P of the organic light emitting diode display illustrated in FIG. 3, respectively, and FIG. 10 is a graph illustrating light absorbing ratio of a light absorbing layer of the organic light emitting diode display according to an exemplary embodiment of the present invention.

Referring to FIGS. 2 and 3, a buffer layer 111 may be positioned on an insulation substrate 110 made of transparent glass or plastic. The buffer layer 111 may prevent an impurity from penetrating, and a surface thereof may be flat. The buffer layer 111 may include silicon nitride (SiNx), silicon oxide (SiO2), silicon oxynitride (SiOxNy), and the like. The buffer layer 111 may be omitted.

A plurality of first semiconductors 154a and a plurality of second semiconductors 154b may be formed on the buffer layer 111. The first semiconductor 154a may include a channel region (not illustrated), and a source region (not illustrated) and a drain region (not illustrated) which are positioned at both sides of the channel region and doped. The second semiconductor 154b may include a channel region 152b, and a source region 153b and a drain region 155b which are positioned at both sides of the channel region 152b and doped. The first semiconductor 154a and the second semiconductor 154b may include amorphous silicon, polycrystalline silicon, or an oxide semiconductor.

A gate insulating layer 140 made of silicon nitride (SiNx) or silicon oxide (SiO₂) may be positioned on the first semiconductor 154a and the second semiconductor 154b.

A plurality of scanning signal lines 121 including a first control electrode 124a and a plurality of gate conductors including a second control electrode 124b may be formed on the gate insulating layer 140.

The scanning signal line 121 may transfer a scanning signal and may mainly extend in a horizontal direction. The first control electrode 124a may extend upward from the scanning signal line 121. The second control electrode 124b may be separated from the scanning signal line 121. Although not illustrated, the second control electrode 124b may include a storage electrode (not illustrated) elongated in a vertical direction. The first control electrode 124a may be overlapped with a part of the first semiconductor 154a, particularly, the channel region, and the second control electrode 124b may be overlapped with a part of the second semiconductor 154b, particularly, the channel region 152b.

A first passivation layer 180a may be positioned on the gate insulating layer 140 and the gate conductor including a second control electrode 124b. The first passivation layer 180a and the gate insulating layer 140 may include a contact hole 183a exposing the source region of the first semiconductor 154a, a contact hole 185a exposing the drain region of the first semiconductor 154a, a contact hole 183b exposing the source region 153b of the second semiconductor 154b, and a contact hole 185b exposing the drain region 155b. The first passivation layer 180a may include a contact hole 184 exposing the second control electrode 124b.

A plurality of data conductors including a plurality of data lines 171, a plurality of driving voltage lines 172, and a plurality of first output electrodes 175a and a plurality of second output electrodes 175b may be formed on the first passivation layer 180a.

The data line 171 may transfer a data voltage and mainly extends in a vertical direction to cross the scanning signal line 121. Each data line 171 may include a plurality of first input electrodes 173a which extends toward the first control electrode 124a.

The driving voltage line 172 may transfer a driving voltage and mainly extends in a vertical direction to cross the scanning signal line 121. Each driving voltage line 172 may include a plurality of second input electrode 173b which extends toward the second control electrode 124b. In the case where the second control electrode 124b includes the storage electrode, the driving voltage line 172 may include a portion overlapped with the storage electrode.

The first and second output electrodes 175a and 175b may be separated from each other to have island shapes, and may be separated from the data line 171 and the driving voltage line 172. The first input electrode 173a and the first output electrode 175a may face each other on the first semiconductor 154a, and the second input electrode 173b and the second output electrode 175b may face each other on the second semiconductor 154b.

The first input electrode 173a and the first output electrode 175a may be connected to the source region and the drain region of the first semiconductor 154a through the contact holes 183a and 185a, respectively. The first output electrode 175a may be connected to the second control electrode 124b through the contact hole 184. The second input electrode 173b and the second output electrode 175b may be connected to the source region 153b and the drain region 155b of the second semiconductor 154b through the contact holes 183b and 185b, respectively.

The first control electrode 124a, the first input electrode 173a, and the first output electrode 175a may form a switching transistor Qs together with the first semiconductor 154a, and the second control electrode 124b, the second input electrode 173b, and the second output electrode 175b may form a driving transistor Qd together with the second semiconductor 154b. The structure of the switching transistor Qs and the driving transistor Qd is not limited thereto, but may be variously modified.

A second passivation layer 180b made of an inorganic insulator such as silicon nitride or silicon oxide may be positioned on the data conductor (for example, data line 171). The second passivation layer 180b may have a flat surface by removing a step in order to increase light emission efficiency of the organic light emitting element to be formed thereon. The second passivation layer 180b may include a contact hole 185c exposing the second output electrode 175b.

A plurality of pixel electrodes 191 and auxiliary electrodes 199 may be positioned on the second passivation layer 180b.

The pixel electrode 191 of each pixel PX may be is physically and electrically connected with the second output electrode 175b through the contact hole 185c of the second passivation layer 180b.

The auxiliary electrode 199 may be separated from the pixel electrode 191 to transfer a common voltage Vss. The auxiliary electrode 199 may be formed in a same layer as the pixel electrode 191 and may include a layer configuring the pixel electrode 191. The auxiliary electrodes 199 may be connected to each other all over the display area of the organic light emitting diode display.

Referring to FIGS. 4 and 5, the auxiliary electrode 199 may have a lattice shape surrounding the pixel electrode 191 of each pixel PX. For example, the auxiliary electrode 199 may have a lattice shape surrounding each pixel electrode 191 as illustrated in FIG. 4, and may have a lattice shape surrounding two or more pixel electrodes 191 in a horizontal direction or vertical direction as illustrated in FIG. 5. Further, the auxiliary electrodes 199 may be disposed at a uniform density throughout the display area, and may be disposed at a different density according to a position. However, the shape of the auxiliary electrode 199 is not limited thereto but may be variously modified.

The pixel electrode 191 according to the exemplary embodiment of the present invention may include a semi-transmitting conductive material or a reflective conductive material, and the auxiliary electrode 199 may include a layer included in the pixel electrode 191.

Referring to FIG. 6, the pixel electrode 191 and the auxiliary electrode 199 according to the exemplary embodiment of the present invention may have the same deposition structure.

The pixel electrode 191 and the auxiliary electrode 199 according to the exemplary embodiment of the present invention may include reflective layers 193a and 193b which may reflect at least a part of light, respectively. The reflective layers 193a and 193b may be made of a metal having high reflectivity such as silver (Ag) or aluminum (Al), and thicknesses thereof may be about 50 Å to 250 Å, but are not limited thereto. The reflective layers 193a and 193b may serve as a semi-transmitting layer in the case where only a part of incident light is reflected.

The pixel electrode 191 and the auxiliary electrode 199 may further include lower layers 192a and 192b and upper layers 194a and 194b which are positioned below and above the reflective layers 193a and 193b, respectively, and contact the reflective layers 193a and 193b. The lower layers 192a and 192b and the upper layers 194a and 194b may be made of transparent conductive oxide such as indium tin oxide (ITO) or indium zinc oxide (IZO). The lower layers 192a and 192b and the upper layers 194a and 194b may improve adhesion between the reflective layers 193a and 193b and another layer and prevent corrosion. Particularly, the lower layers 192a and 192b may protect the reflective layers 193a and 193b from oxygen or moisture which may be discharged from the second passivation layer 180b. At least one of the lower layers 192a and 192b and the upper layers 194a and 194b may be omitted.

The pixel electrode 191 and the auxiliary electrode 199 according to the exemplary embodiment of the present invention may further include light absorbing layers 195a and 195b, respectively. The light absorbing layers 195a and 195b, as layers which may absorb light to diffuse heat, may include at least one metal having high light absorbing ratio such as molybdenum (Mo), chromium (Cr), tungsten (W), and nickel (Ni). The light absorbing layers 195a and 195b may be formed with a single layer of a metal such as molybdenum (Mo), chromium (Cr), tungsten (W), and nickel (Ni), and may be formed in a deposition structure of the metal layer and a transparent conductive oxide. An example of the deposition structure of the light absorbing layers 195a and 195b may include a structure in which at least one metal layer having high light absorbing ratio and at least one transparent conductive oxide layer such as a TCO are alternately deposited.

According to the exemplary embodiment of the present invention, the light absorbing layers 195a and 195b of the pixel electrode 191 and the auxiliary electrode 199 may be positioned between the lower layers 192a and 192b and the reflective layers 193a and 193b, but are not limited thereto. The light absorbing layers 195a and 195b may be patterned together when the lower layers 192a and 192b, the reflective layers 193a and 193b, and the upper layers 194a and 194b are patterned.

Referring to FIG. 7, the pixel electrode 191 and the auxiliary electrode 199 according to the exemplary embodiment of the present invention have almost the same structure as those of the exemplary embodiment illustrated in FIG. 6 described above, but the pixel electrode 191 and the auxiliary electrode 199 according to an exemplary embodiment of the present invention may have a different deposition structure. That is, the auxiliary electrode 199 further includes a light absorbing layer 195b, and the pixel electrode 191 may not include a light absorbing layer. Since the description of the light absorbing layer 195b is the same as the above exemplary embodiment, a detailed description is omitted.

According to an exemplary embodiment of the present invention, the light absorbing layer 195b of the auxiliary electrode 199 may be positioned on the upper layer 194b. The light absorbing layer 195b of the auxiliary electrode 199 may be patterned after the lower layer 192b, the reflective layer 193b, and the upper layer 194b are patterned.

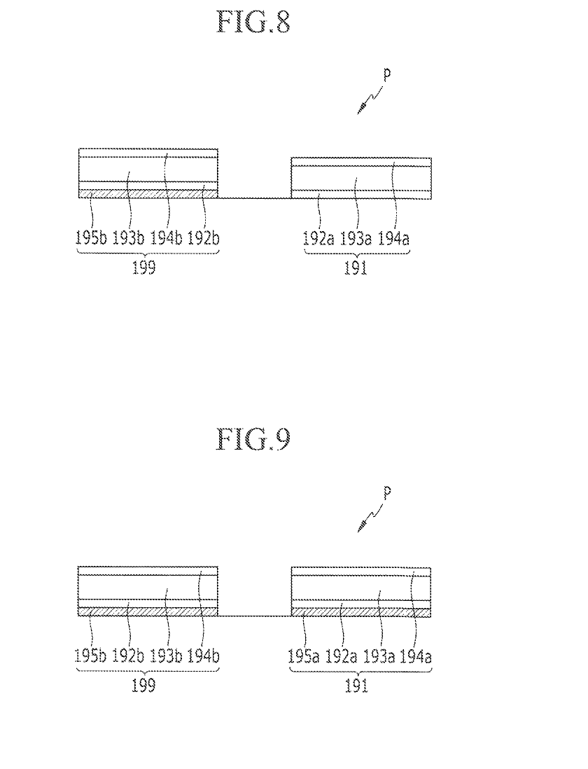

Referring to FIG. 8, the pixel electrode 191 and the auxiliary electrode 199 according to the exemplary embodiment of the present invention may have almost the same structure as those of the exemplary embodiment illustrated in FIG. 7 described above, but the light absorbing layer 195b of the auxiliary electrode 199 may be positioned below the lower layer 192b. The light absorbing layer 195b of the auxiliary electrode 199 may be first patterned before the lower layer 192b, the reflective layer 193b, and the upper layer 194b are patterned.

Referring to FIG. 9, the pixel electrode 191 and the auxiliary electrode 199 according to the exemplary embodiment of the present invention may have almost the same structure as those of the exemplary embodiment illustrated in FIG. 6 described above, but positions of the light absorbing layers 195a and 195b may be different. According to an exemplary embodiment of the present invention, the light absorbing layers 195a and 195b of the pixel electrode 191 and the auxiliary electrode 199 may be positioned below the lower layers 192a and 192b. The light absorbing layers 195a and 195b may be patterned together when the lower layers 192a and 192b, the reflective layers 193a and 193b, and the upper layers 194a and 194b are patterned, or may be first patterned separately.

Referring to FIG. 10, the light absorbing layers 195a and 195b according to the exemplary embodiment of the present invention may be layers having high light absorbing ratio as described above, and particularly, absorb approximately 70% or more of irradiated light in a visible-ray area to change the absorbed light into heat. Accordingly, when light of a flash lamp or a laser which emits light in a visible-ray area is irradiated to the pixel electrode 191 or the auxiliary electrode 199 including the light absorbing layers 195a and 195b, absorbed light energy may be converted into heat energy to be heated. However, a wavelength band of light mainly absorbed by the light absorbing layers 195a and 195b is not limited thereto, and the light absorbing layers 195a and 195b may include various materials which may efficiently absorb light of a main wavelength band of a light emitter which is used for light irradiation.

Referring back to FIGS. 2 to 5, a pixel defining layer 360 (referred to as a partition) having a plurality of openings exposing the pixel electrode 191 and a plurality of openings exposing the auxiliary electrode 199 may be positioned on the second passivation layer 180b. The openings of the pixel defining layer 360 exposing the pixel electrode 191 may define each pixel area. The pixel defining layer 360 may be overlapped with a part of each of the pixel electrode 191 and the auxiliary electrode 199. The pixel defining layer 360 may be omitted.

A light emitting member 370 may be positioned on the pixel defining layer 360 and the pixel electrode 191. The light emitting member 370 may include a first organic common layer 371, a plurality of light emitting layers 373, and a second organic common layer 375 which are sequentially deposited.

The first organic common layer 371 may include, for example, at least one of a hole injecting layer and a hole transport layer which are sequentially deposited. The first organic common layer 371 may be formed all over the display area in which the pixels PX are disposed.

The light emitting layer 373 may be positioned on the pixel electrode 191 of each corresponding pixel PX. The light emitting layer 373 may be made of an organic material which uniquely emits light of the primary colors such as red, green, and blue, and may have a structure in which a plurality of organic material layers emitting light of different colors are deposited.

For example, a red organic light emitting layer 373 may be deposited on the first organic common layer 371 of a pixel PX displaying red, a green organic light emitting layer 373 may be deposited on the first organic common layer 371 of a pixel PX displaying green, and a blue organic light emitting layer 373 may be deposited on the first organic common layer 371 of a pixel PX displaying blue. However, it is not limited thereto, and an organic light emitting layer displaying one primary color may be deposited on the pixels displaying different colors. According to another exemplary embodiment of the present invention, the light emitting layer 373 may include a white light emitting layer displaying white.

The second organic common layer 375 may include, for example, at least one of an electron transport layer and an electron injecting layer which are sequentially deposited. The second organic common layer 375 may be formed all over the display area in which the pixels PX are disposed.

The first and second organic common layers 371 and 375 may be layers for improving light emitting efficiency of the light emitting layer 373, and any one of the first and second organic common layers 371 and 375 may be omitted.

The light emitting member 370 may include a plurality of contact holes 378 exposing the auxiliary electrode 199. The contact holes 378 may have a band shape formed along the auxiliary electrode 199 or may have an island shape. FIGS. 2, 4, and 5 illustrate examples in which the contact holes 378 of the light emitting member 370 have a discontinuous island shape. Referring to FIGS. 4 and 5, the contact holes 378 of the light emitting member 370 may be disposed in a vertical direction or a horizontal direction on at least one pixel PX cycle, but are not limited thereto.

A common electrode 270 transferring a common voltage Vss may be formed on the light emitting member 370. The common electrode 270 may include a transparent conductive material. For example, the common electrode 270 may be made of a transparent conductive material, or formed by thinly depositing a metal including calcium (Ca), barium (Ba), magnesium (Mg), aluminum (Al), silver (Ag), and the like to have a light transmitting property.

The common electrode 270 may be electrically and physically connected with the auxiliary electrode 199 through the plurality of contact holes 378 of the light emitting member 370 to receive a common voltage Vss. Accordingly, by decreasing a load of the common electrode 270 and reducing non-uniformity of the common voltage Vss due to voltage drop to increase uniformity, display stains may be removed and display quality may be increased. In order to further increase uniformity of the common voltage Vss all over the display area of the organic light emitting diode display, resistance for a unit area of the auxiliary electrode 199 may be lower than resistance for a unit area of the common electrode 270.

An encapsulation layer (not illustrated) may be further formed on the common electrode 270. The encapsulation layer may encapsulate the light emitting member 370 and the common electrode 270, thereby preventing moisture and/or oxygen from penetrating from the outside.

The pixel electrode 191, the light emitting member 370, and the common electrode 270 of each pixel PX may form the organic light emitting element LD, and one of the pixel electrode 191 and the common electrode 270 is a cathode and the other is an anode. Further, the storage electrode and the driving voltage line 172 which are overlapped with each other may form a storage capacitor Cst.

The organic light emitting diode display according to the exemplary embodiment of the present invention may be a top emission type in which light is emitted to the top of the substrate 110 to display an image. However, it is not limited thereto, and the organic light emitting diode display according to the exemplary embodiment of the present invention may be a bottom emission type in which light is emitted to the bottom of the substrate 110, and in this case, light transmitting properties of the pixel electrode 191 and the common electrode 270 may be changed. For example, the common electrode 270 may include a reflective material, and the pixel electrode 191 may include a semi-transmitting material or a transmitting material.

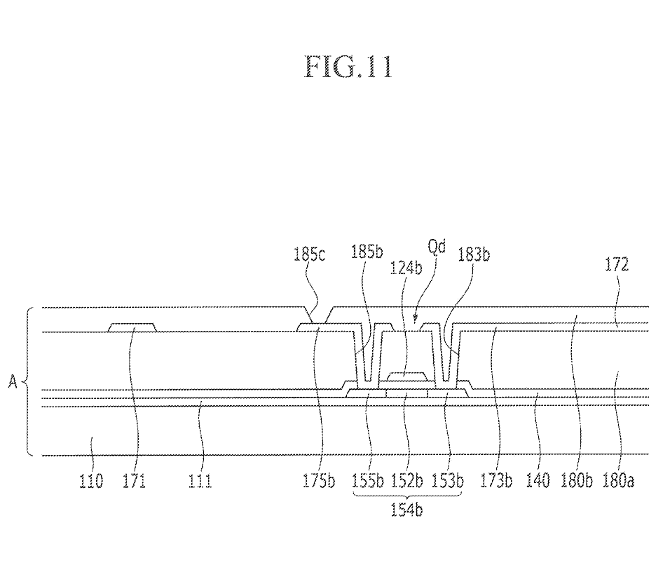

Hereinafter, a method for manufacturing an organic light emitting diode display according to an exemplary embodiment of the present invention will be described in detail with reference to FIGS. 11 to 17.

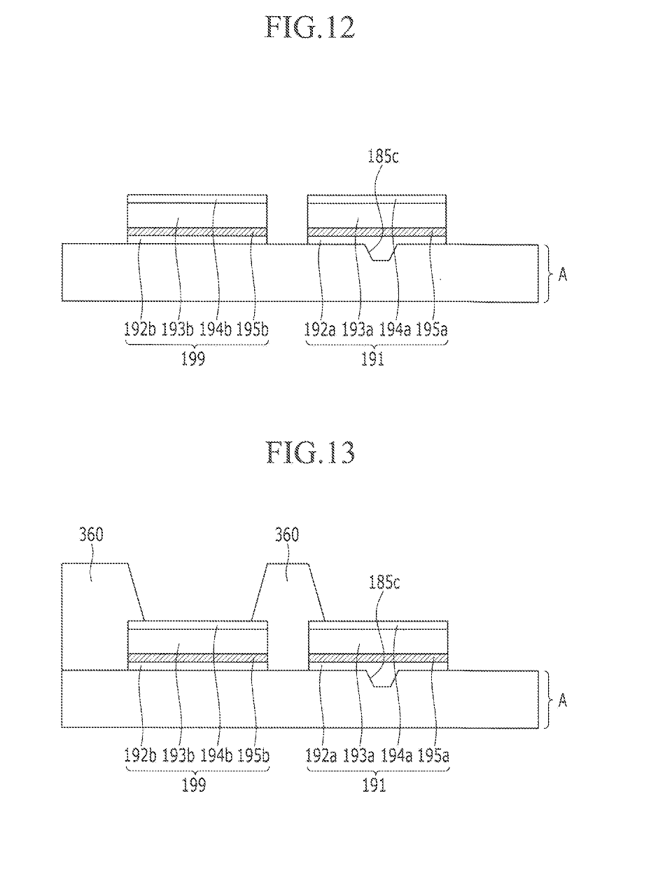

FIG. 11 is a cross-sectional view in one step of a manufacturing process of the organic light emitting diode display according to the exemplary embodiment of the present invention, and FIGS. 12 to 17 are cross-sectional views illustrating respective steps of a manufacturing method of the organic light emitting diode display according to the exemplary embodiment of the present invention in sequence, and cross-sectional views illustrating steps after the manufacturing step illustrated in FIG. 11.

First, referring to FIG. 11, a buffer layer 111 may be formed by depositing silicon nitride, silicon oxide, silicon oxynitride, and the like on an insulation substrate 110 made of transparent glass. The buffer layer 111 may be omitted.

Next, a plurality of the first semiconductors 154a including a source region, a drain region, and a channel region (not illustrated in FIG. 11), and a plurality of the second semiconductors 154b including a source region 153b, a drain region 155b, and a channel region 152b may be formed by depositing and patterning amorphous silicon, polysilicon, or oxide semiconductor on the buffer layer 111 and doping a partial region of the deposited semiconductor layer with an impurity.

Next, a gate insulating layer 140 may be formed by depositing silicon nitride (SiNx) or silicon oxide (SiO₂) on the first semiconductor 154a and the second semiconductor 154b.

Next, a plurality of scanning signal lines 121 including a first control electrode 124a (not illustrated in FIG. 11) and a plurality of gate conductors including a second control electrode 124b may be formed by depositing and patterning a metal such as an aluminum-based metal, a silver-based metal, and a copper-based metal on the gate insulating layer 140 by a method such as sputtering.

Next, a first passivation layer 180a may be formed by depositing an insulating material on the gate insulating layer 140 and the gate conductor. Next, a plurality of contact holes 183a (not illustrated in FIG. 11), 185a (not illustrated in FIG. 11), 183b, 185b, and 184 (not illustrated in FIG. 11) may be formed by patterning the first passivation layer 180a.

Next, a plurality of data conductors including a plurality of data lines 171, a plurality of driving voltage lines 172, and a plurality of first output electrodes 175a (not illustrated in FIG. 11) and a plurality of second output electrodes 175b may be formed by depositing and patterning a conductive material such as a metal on the first passivation layer 180a by a sputtering method and the like.

Next, a second passivation layer 180b may be formed by depositing an organic insulator such as silicon nitride or silicon oxide on the data conductor. Next, a contact hole 185c may be formed by patterning the second passivation layer 180b.

As a result, a portion A illustrated in FIG. 11 may be manufactured.

Next, manufacturing steps after manufacturing the portion A will be described with reference to FIGS. 12 to 17.

First, referring to FIG. 12, a pixel electrode 191 and an auxiliary electrode 199 having the same deposition structure are formed on the portion A as illustrated in FIG. 11 like the exemplary embodiment illustrated in FIG. 6.

In detail, a transparent conductive oxide such as IZO or ITO may be deposited on the portion A, at least one metal including molybdenum (Mo), chromium (Cr), tungsten (W), and nickel (Ni) having high light absorbing ratio may be deposited or the metal layer and the transparent conductive oxide may be alternately deposited thereon, a metal having high reflectivity such as silver (Ag) or aluminum (Al) may be deposited thereon, and finally, transparent conductive oxide such as IZO or ITO may be deposited thereon. Next, by photolithographing the layers deposited on the portion A by using one optical mask, a pixel electrode 191 including a lower layer 192a, a light absorbing layer 195a, a reflective layer 193a, and an upper layer 194a which are sequentially deposited from the bottom, and an auxiliary electrode 199 including a lower layer 192b, a light absorbing layer 195b, a reflective layer 193b, and an upper layer 194b which are sequentially deposited from the bottom may be formed.

Next, referring to FIG. 13, by depositing and patterning a resin such as polyacrylates resin and polyimides or a silica-based inorganic material on the portion A, the pixel electrode 191, and the auxiliary electrode 199, a pixel defining layer 360 having a plurality of openings, which expose the pixel electrode 191 and the auxiliary electrode 199, respectively, may be formed. The formation of the pixel defining layer 360 may be omitted.

Next, referring to FIG. 14, by depositing an organic material all over the display area on the pixel defining layer 360, the pixel electrode 191 and the auxiliary electrode 199, a first organic common layer 371 may be formed. The first organic common layer 371 may include a hole injecting layer and a hole transport layer which are sequentially deposited. Next, by depositing a light emitting organic material in a region corresponding to the pixel electrode 191 of each pixel PX on the first organic common layer 371, a light emitting layer 373 may be formed. In this case, a shadow mask and the like may be used. Next, by depositing an organic material all over the display area on the light emitting layer 373, a second organic common layer 375 may be formed. The second organic common layer 375 may include an electron transport layer and an electron injecting layer which are sequentially deposited. As a result, the light emitting member 370 may be formed. Unlike those illustrated in FIG. 14, any one of the first and second organic common layers 371 and 375 may be omitted.

Next, referring to FIG. 15, an optical mask 30 including an non-light transmitting portion B and a light transmitting portion C may be positioned on the bottom of the portion A. The light transmitting portion C may be positioned at a place corresponding to the auxiliary electrode 199, and the non-light transmitting portion B may include a place corresponding to the pixel electrode 191. Next, light is irradiated to the optical mask 30 and the bottom of the portion A from the lower side of the substrate 110 by using a flash lamp or a laser. Then, the light irradiated to the non-light transmitting portion B of the optical mask 30 is reflected and discharged, and only the light irradiated to the light transmitting portion C locally passes through the optical mask 30 to reach the auxiliary electrode 199.

According to another exemplary embodiment of the present invention, unlike those illustrated in FIG. 15, the light may be irradiated to only the auxiliary electrode 199 by using a light source such as a laser which may locally irradiate light to only the auxiliary electrode 199 without using the optical mask 30.

The light which reaches the auxiliary electrode 199 may be absorbed in the light absorbing layer 195b and converted into heat energy to heat and evaporate or sublimate the first organic common layer 371 or the second organic common layer 375 positioned on the auxiliary electrode 199.

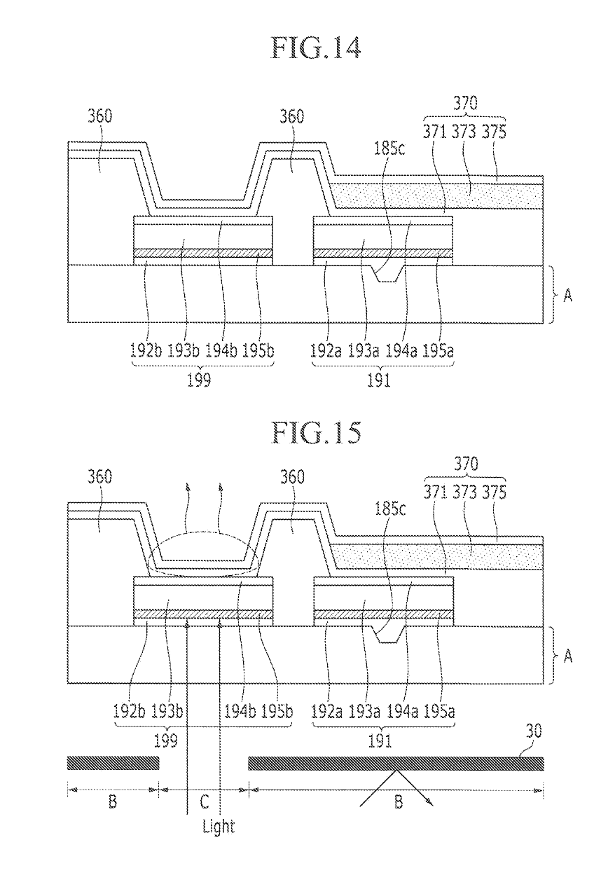

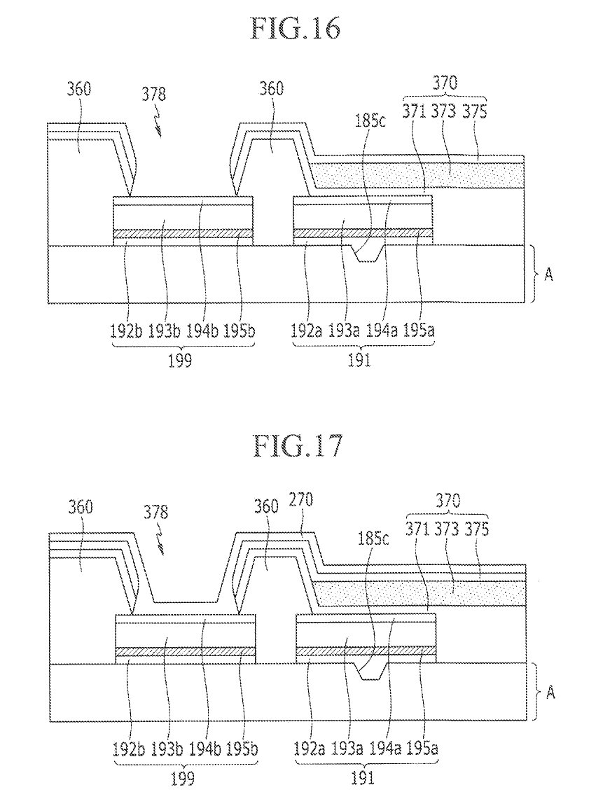

Then, as illustrated in FIG. 16, a contact hole 378 exposing the auxiliary electrode 199 may be formed in the light emitting member 370.

Next, referring to FIG. 17, a common electrode 270 may be formed by depositing a transparent conductive material on the entire surface of the light emitting member 370 or thinly depositing a metal such as calcium (Ca), barium (Ba), magnesium (Mg), aluminum (Al), and silver (Ag). The common electrode 270 may be connected to the auxiliary electrode 199 through the contact hole 378 to receive a common voltage Vss.

As such, according to the method for manufacturing the organic light emitting diode display explained above, since the first and second organic common layers 371 and 375 of the light emitting member 370 on the auxiliary electrode 199 may be removed by a simple method, a manufacturing time and a manufacturing cost may be reduced, and a manufacturing method may be simplified. Further, since the auxiliary electrode 199 includes the light absorbing layer 195b having high light absorbing ratio, the auxiliary electrode 199 itself is not damaged by easily sublimating the first and second organic common layers 371 and 375 on the auxiliary electrode 199 at low energy.

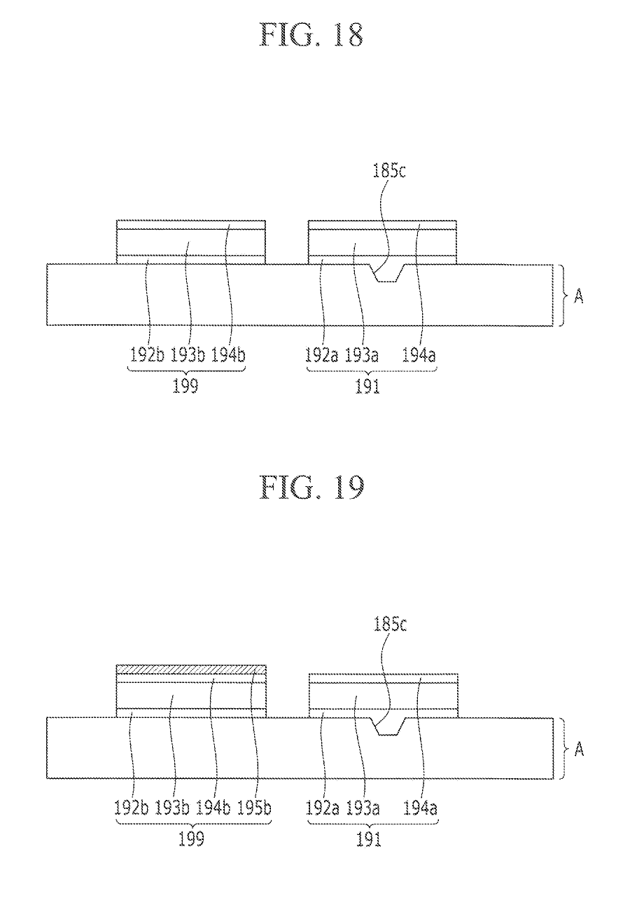

Hereinafter, a method for manufacturing an organic light emitting diode display according to an exemplary embodiment of the present invention will be described with reference to FIGS. 18 to 24 in addition to FIG. 11 described above. The same constituent elements as the exemplary embodiments described above designate the same reference numerals, and the duplicated description is omitted.

FIGS. 18 to 24 are cross-sectional views illustrating respective steps of a manufacturing method of the organic light emitting diode display according to the exemplary embodiment of the present invention in sequence, and cross-sectional views illustrating steps after the manufacturing step illustrated in FIG. 11.

First, as illustrated in FIG. 11, the portion A is formed.

Next, referring to FIGS. 18 and 19 in sequence, a pixel electrode 191 and an auxiliary electrode 199 having different deposition structures may be formed on the portion A like the exemplary embodiment illustrated in FIG. 7 described above.

In detail, referring to FIG. 18, transparent conductive oxide such as IZO or ITO may be deposited on the portion A, a metal having high reflectivity such as silver (Ag) or aluminum (Al) may be deposited, and transparent conductive oxide such as IZO or ITO may be deposited thereon. Next, by photolithographing the layers deposited on the portion A by using one optical mask, a pixel electrode 191 including a lower layer 192a, a reflective layer 193a, and an upper layer 194a which are sequentially deposited from the bottom, and a part of an auxiliary electrode 199 including a lower layer 192b, a reflective layer 193b, and an upper layer 194b which are sequentially deposited from the bottom may be formed.

Next, referring to FIG. 19, by depositing at least one metal including molybdenum (Mo), chromium (Cr), tungsten (W), and nickel (Ni) having high light absorbing ratio on the front side including the upper layer 194b or alternately depositing and patterning such metal layer and a transparent conductive oxide, the light absorbing layer 195b positioned on the upper layer 194b may be formed. As a result, the auxiliary electrode 199 including the lower layer 192b, the reflective layer 193b, the upper layer 194b, and the light absorbing layer 195b which are deposited from the bottom in sequence may be formed.

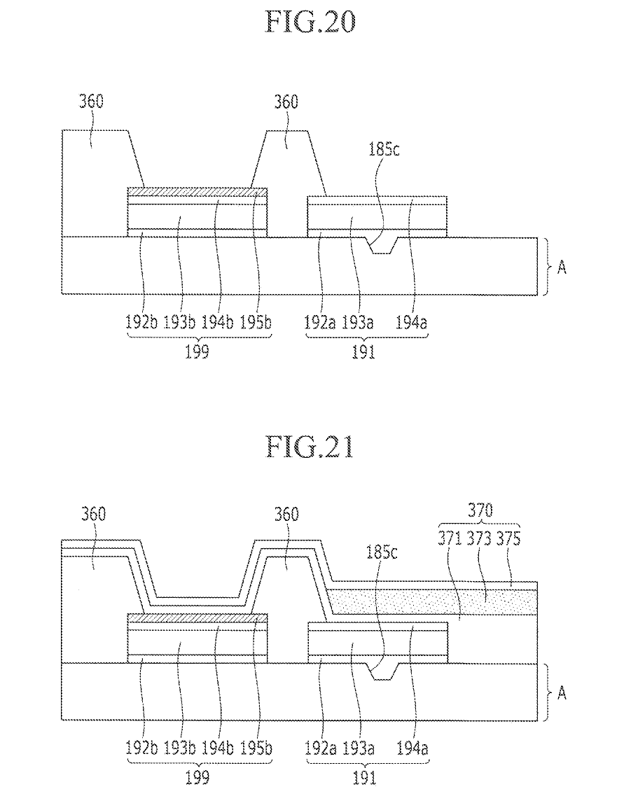

Next, referring to FIG. 20, by depositing and patterning a resin such as polyacrylates resin and polyimides or a silica-based inorganic material on the portion A, the pixel electrode 191, and the auxiliary electrode 199, a pixel defining layer 360 having a plurality of openings, which expose the pixel electrode 191 and the auxiliary electrode 199, respectively, may be formed.

Next, referring to FIG. 21, by depositing an organic material all over the display area on the pixel defining layer 360, the pixel electrode 191, and the auxiliary electrode 199, a first organic common layer 371 may be formed. Next, by depositing a light emitting organic material in a region corresponding to the pixel electrode 191 of each pixel PX on the first organic common layer 371, a light emitting layer 373 may be formed. Next, by depositing an organic material all over the display area on the light emitting layer 373, a second organic common layer 375 may be formed. As a result, the light emitting member 370 may be formed. Unlike those illustrated in FIG. 21, any one of the first and second organic common layers 371 and 375 may be omitted.

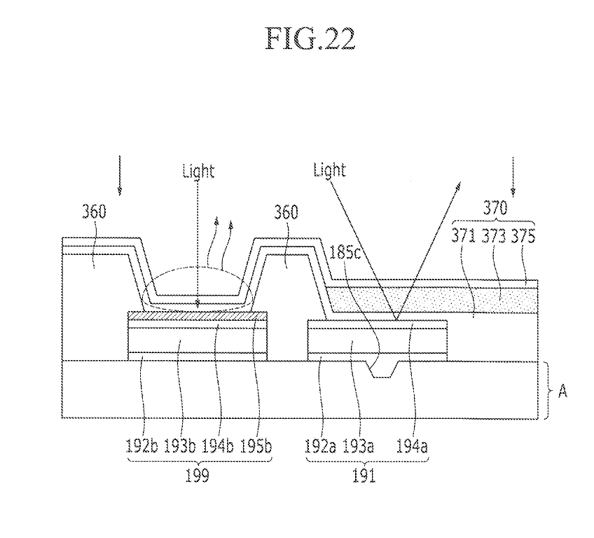

Next, referring to FIG. 22, light is irradiated to the front side of the portion A from the upper side of the substrate 110 by using a flash lamp or a laser. The light which reaches the pixel electrode 191 is reflected and discharged, and the light which reaches the auxiliary electrode 199 is absorbed in the light absorbing layer 195b and converted into heat energy to heat and evaporate or sublimate the first organic common layer 371 or the second organic common layer 375 positioned on the auxiliary electrode 199.

According to another exemplary embodiment of the present invention, the optical mask 30 may be used during light irradiation as described above. In this case, since the optical mask 30 includes a light transmitting portion corresponding to the auxiliary electrode 199 and may block light so as not to be irradiated to the pixel electrode 191, the pixel electrode 191 may further include a light absorbing layer 195a thereon like the auxiliary electrode 199. In the case of such a structure, light may be irradiated to only the auxiliary electrode 199 by using a light source such as a laser which may locally irradiate light to only the auxiliary electrode 199 without using the optical mask 30.

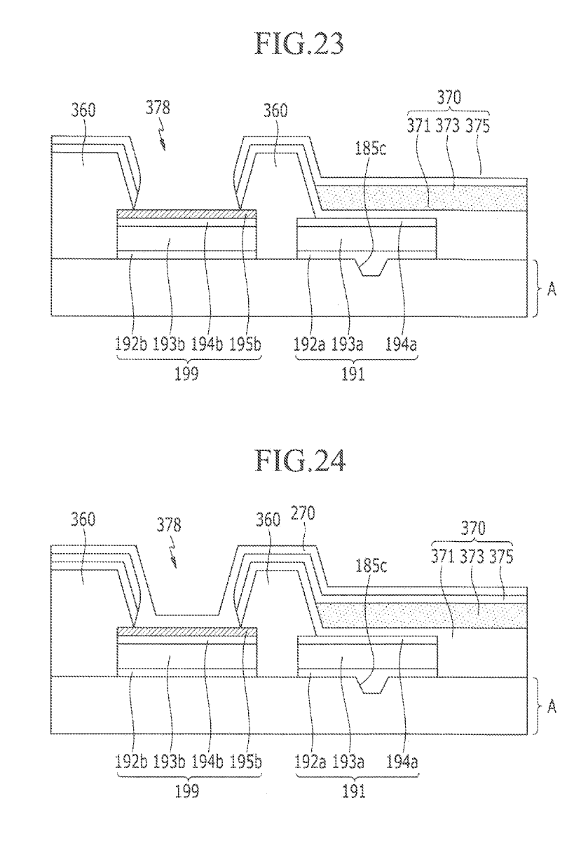

Next, referring to FIG. 23, a contact hole 378 exposing the auxiliary electrode 199 may be formed in the light emitting member 370.

Next, referring to FIG. 24, a common electrode 270 may be formed by depositing a transparent conductive material on the entire surface of the light emitting member 370 or thinly depositing a metal such as calcium (Ca), barium (Ba), magnesium (Mg), aluminum (Al), and silver (Ag).

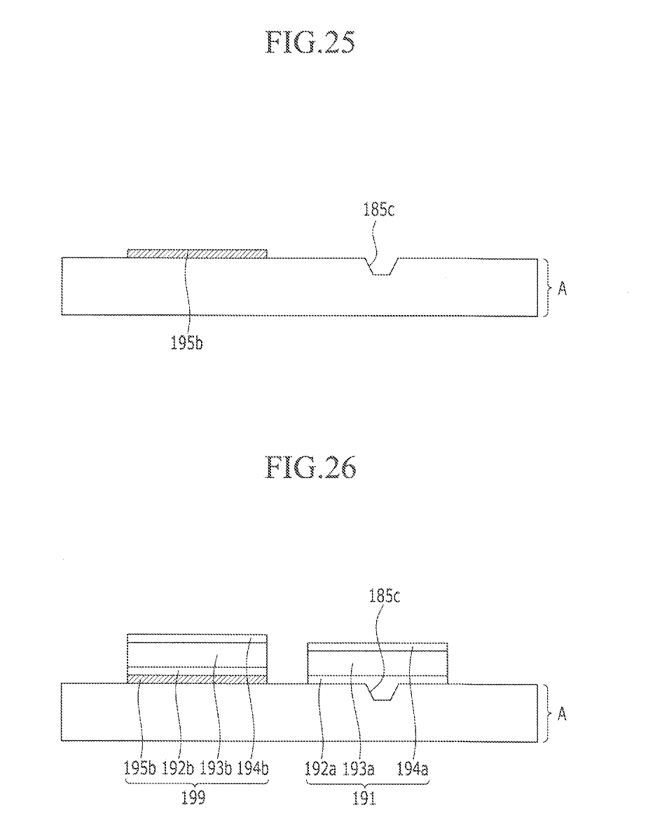

Hereinafter, a method for manufacturing an organic light emitting diode display according to an exemplary embodiment of the present invention will be described with reference to FIGS. 25 to 31 in addition to FIG. 11 described above. The same constituent elements as the exemplary embodiments described above designate the same reference numerals, and the duplicated description is omitted.

FIGS. 25 to 31 are cross-sectional views illustrating respective steps of a manufacturing method of the organic light emitting diode display according to the exemplary embodiment of the present invention in sequence, and cross-sectional views illustrating steps after the manufacturing step illustrated in FIG. 11.

First, as illustrated in FIG. 11, the portion A is formed.

Next, referring to FIG. 25, by depositing at least one metal such as molybdenum (Mo), chromium (Cr), tungsten (W), and nickel (Ni) having high light absorbing ratio or alternately depositing and then patterning the metal layer and a transparent conductive oxide on the portion A, the light absorbing layer 195b may be formed.

Next, referring to FIG. 26, transparent conductive oxide such as IZO or ITO may be deposited on the light absorbing layer 195b and the portion A, a metal having high reflectivity such as silver (Ag) or aluminum (Al) may be deposited thereon, transparent conductive oxide such as IZO or ITO may be deposited thereon, and thereafter, by photolithographing the deposited layers by using one optical mask, a pixel electrode 191 including a lower layer 192a, a reflective layer 193a, and an upper layer 194a which are sequentially deposited from the bottom, and a lower layer 192b, a reflective layer 193b, and an upper layer 194b which are sequentially deposited from the bottom may be formed. The lower layer 192b, the reflective layer 193b, and the upper layer 194b form the auxiliary electrode 199 together with the light absorbing layer 195b.

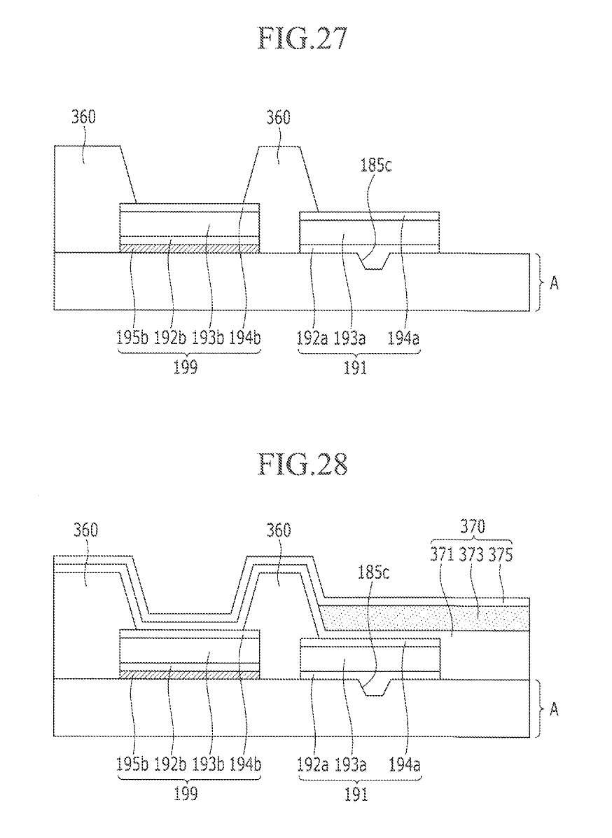

Next, referring to FIG. 27, by depositing and patterning a resin such as polyacrylates resin and polyimides or a silica-based inorganic material on the portion A, the pixel electrode 191, and the auxiliary electrode 199, a pixel defining layer 360 having a plurality of openings, which expose the pixel electrode 191 and the auxiliary electrode 199, respectively, may be formed.

Next, referring to FIG. 28, a first organic common layer 371 may be formed all over the display area on the pixel defining layer 360, the pixel electrode 191, and the auxiliary electrode 199. Next, a light emitting layer 373 may be formed in a region corresponding to the pixel electrode 191 of each pixel PX on the first organic common layer 371. Next, a second organic common layer 375 may be formed all over the display area on the light emitting layer 373. As a result, the light emitting member 370 may be formed. Unlike those illustrated in FIG. 28, any one of the first and second organic common layers 371 and 375 may be omitted.

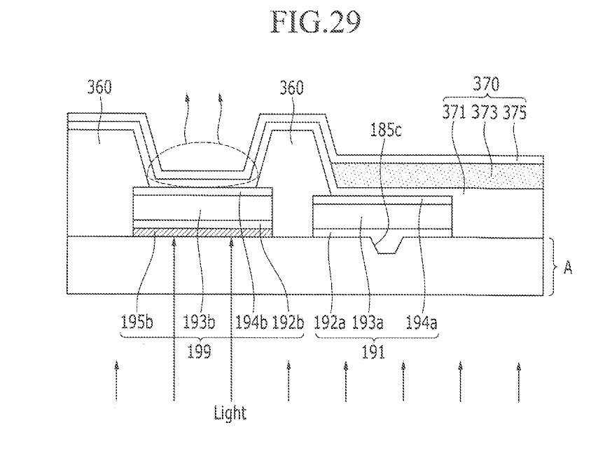

Next, referring to FIG. 29, light is irradiated to the rear side of the portion A from the lower side of the substrate 110 by using a flash lamp or a laser. The light which reaches the pixel electrode 191 is reflected and discharged, and the light which reaches the auxiliary electrode 199 is absorbed in the light absorbing layer 195b and converted into heat energy to heat and evaporate or sublimate the first organic common layer 371 or the second organic common layer 375 positioned on the auxiliary electrode 199.

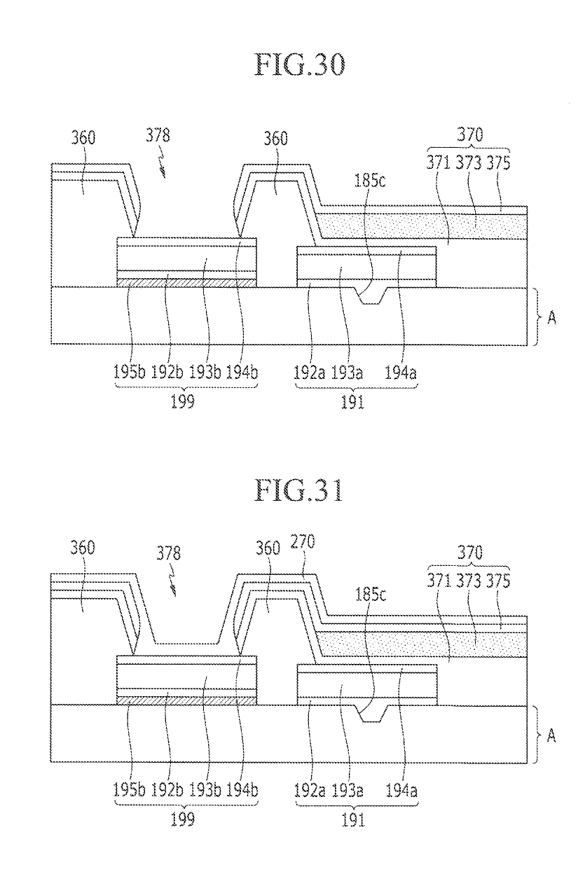

As a result, as illustrated in FIG. 30, a contact hole 378 exposing the auxiliary electrode 199 may be formed in the light emitting member 370.

Next, referring to FIG. 31, a common electrode 270 may be formed by depositing a transparent conductive material on the entire surface of the light emitting member 370 or thinly depositing a metal such as calcium (Ca), barium (Ba), magnesium (Mg), aluminum (Al), and silver (Ag).

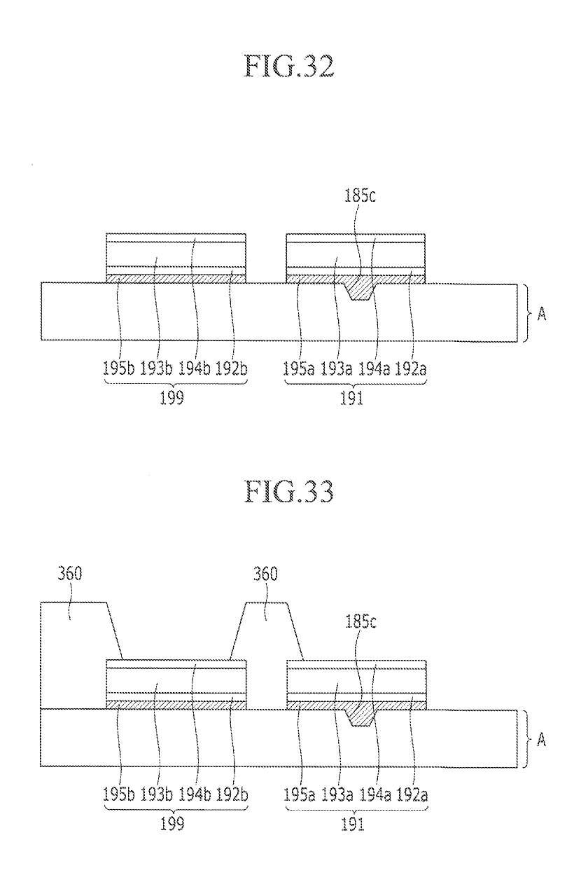

Finally, a method for manufacturing an organic light emitting diode display according to an exemplary embodiment of the present invention will be described with reference to FIGS. 32 to 37 together with FIG. 11 described above. The same constituent elements as the exemplary embodiments described above designate the same reference numerals, and the duplicated description is omitted.

FIGS. 32 to 37 are cross-sectional views illustrating respective steps of a manufacturing method of the organic light emitting diode display according to the exemplary embodiment of the present invention in sequence, and cross-sectional views illustrating steps after the manufacturing step illustrated in FIG. 11.

First, as illustrated in FIG. 11, the portion A is formed.

Next, referring to FIG. 32, a pixel electrode 191 and an auxiliary electrode 199 having the same deposition structure may be formed on the portion A like the exemplary embodiment illustrated in FIG. 9 described above.

In detail, at least one metal including molybdenum (Mo), chromium (Cr), tungsten (W), and nickel (Ni) having high light absorbing ratio may be deposited or the metal layer and a transparent conductive oxide may be alternately deposited on the portion A, transparent conductive oxide such as IZO or ITO may be deposited thereon, a metal having high reflectivity such as silver (Ag) or aluminum (Al) may be deposited thereon, and finally, transparent conductive oxide such as IZO or ITO may be deposited thereon. Next, by photolithographing the layers deposited on the portion A by using one optical mask, the pixel electrode 191 including a light absorbing layer 195a, a lower layer 192a, a reflective layer 193a, and an upper layer 194a which are sequentially deposited from the bottom, and the auxiliary electrode 199 including a light absorbing layer 195a, a lower layer 192b, a reflective layer 193b, and an upper layer 194b which are sequentially deposited from the bottom may be formed.

Next, referring to FIG. 33, a pixel defining layer 360 having a plurality of openings, which expose the pixel electrode 191 and the auxiliary electrode 199, respectively, may be formed on the portion A, the pixel electrode 191, and the auxiliary electrode 199.

Next, referring to FIG. 34, a first organic common layer 371 may be formed all over the display area on the pixel defining layer 360, the pixel electrode 191, and the auxiliary electrode 199, a light emitting layer 373 may be formed in a region corresponding to the pixel electrode 191 of each pixel PX on the first organic common layer 371, and a second organic common layer 375 may be formed all over the display area on the light emitting layer 373. As a result, the light emitting member 370 may be formed. Unlike those illustrated in FIG. 34, any one of the first and second organic common layers 371 and 375 may be omitted.

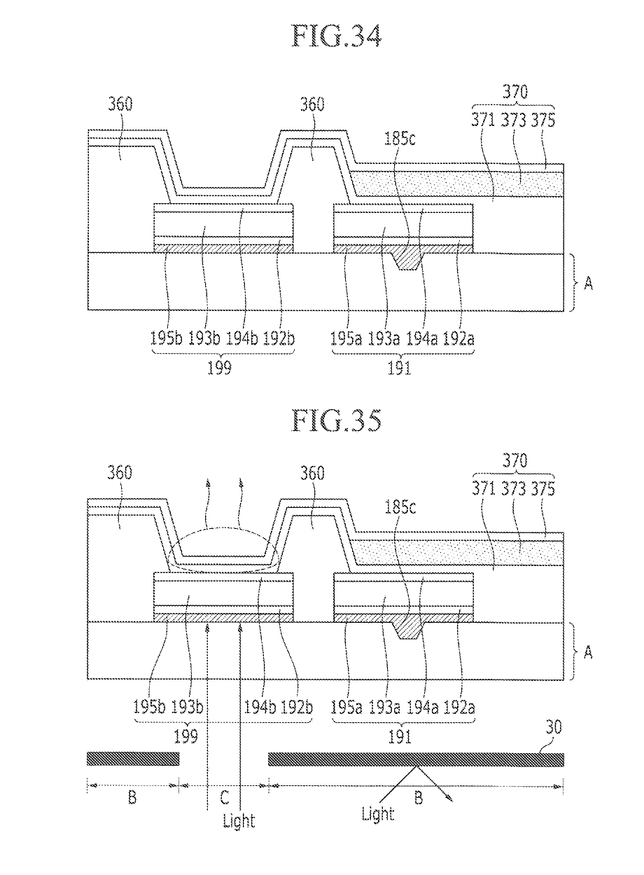

Next, referring to FIG. 35, an optical mask 30 including an non-light transmitting portion B and a light transmitting portion C may be positioned on the bottom of the portion A. The light transmitting portion C may be positioned at a place corresponding to the auxiliary electrode 199, and the non-light transmitting portion B includes a place corresponding to the pixel electrode 191. Next, light is irradiated to the optical mask 30 and the bottom of the portion A from the lower side of the substrate 110 by using a flash lamp or a laser. Then, the light irradiated to the non-light transmitting portion B of the optical mask 30 is reflected and discharged, and only the light irradiated to the light transmitting portion C locally passes through the optical mask 30 to reach the auxiliary electrode 199.

According to another exemplary embodiment of the present invention, unlike those illustrated in FIG. 35, the light may be irradiated to only the auxiliary electrode 199 by using a light source such as a laser which may locally irradiate light to only the auxiliary electrode 199 without using the optical mask 30.

The light which reaches the auxiliary electrode 199 may be absorbed in the light absorbing layer 195b and converted into heat energy to heat and evaporate or sublimate the first organic common layer 371 or the second organic common layer 375 positioned on the auxiliary electrode 199.

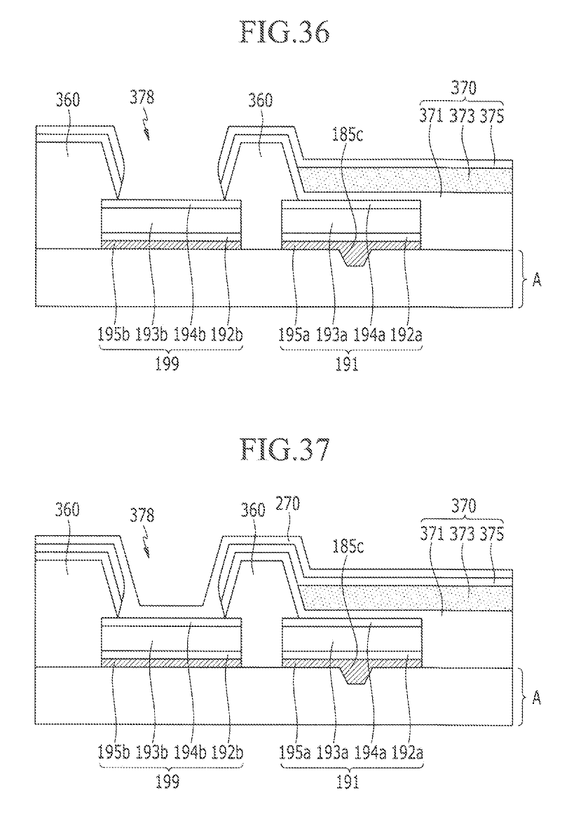

Then, as illustrated in FIG. 36, a contact hole 378 exposing the auxiliary electrode 199 may be formed in the light emitting member 370.

Next, referring to FIG. 37, a common electrode 270 may be formed on the front side of the light emitting member 370.

Hereinabove, the organic light emitting diode displays according to the exemplary embodiments of the present invention are mainly described as examples which are the top emission types, but are not limited thereto and may be bottom emission types. In this case, light transmitting properties of the pixel electrode 191 and the common electrode 270 may be changed. For example, the common electrode 270 may include a reflective material, and the reflective layers 193a and 193b of the pixel electrode 191 and the auxiliary electrode 199 may include a semi-transmitting material or a transmitting material.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a driving switching element;
a pixel electrode connected with the driving switching element;
an auxiliary electrode separated from the pixel electrode and positioned in a same layer as the pixel electrode;
an organic common layer positioned on the pixel electrode and the auxiliary electrode and including a contact hole positioned on the auxiliary electrode; and
a common electrode positioned on the organic common layer and connected with the auxiliary electrode through the contact hole,
wherein the auxiliary electrode includes a light absorbing layer.

2. The organic light emitting diode display of claim 1, wherein:
the light absorbing layer has a light absorbing ratio of approximately 70% or more.

3. The organic light emitting diode display of claim 2, wherein:
the light absorbing layer comprises at least one metal including molybdenum (Mo), chromium (Cr), tungsten (W), and nickel (Ni).

4. The organic light emitting diode display of claim 1, wherein:
the pixel electrode includes the light absorbing layer.

5. The organic light emitting diode display of claim 4, wherein:
the auxiliary electrode and the pixel electrode each includes a lower layer, the light absorbing layer, a reflective layer, and an upper layer which are sequentially disposed from a bottom.

6. The organic light emitting diode display of claim 4, wherein:
the auxiliary electrode and the pixel electrode each includes the light absorbing layer, a lower layer, a reflective layer, and an upper layer which are sequentially disposed from a bottom.

7. The organic light emitting diode display of claim 1, wherein:
the pixel electrode does not include the light absorbing layer.

8. The organic light emitting diode display of claim 7, wherein:
the auxiliary electrode includes a lower layer, a reflective layer, an upper layer, and the light absorbing layer which are sequentially disposed from a bottom, and
the pixel electrode includes the lower layer, the reflective layer, and the upper layer which are sequentially disposed from the bottom.

9. The organic light emitting diode display of claim 7, wherein:
the auxiliary electrode includes the light absorbing layer, a lower layer, a reflective layer, and an upper layer which are sequentially disposed from a bottom, and
the pixel electrode includes the lower layer, the reflective layer, and the upper layer which are sequentially disposed from the bottom.

10. A method for manufacturing an organic light emitting diode display, the method comprising:
forming a pixel electrode and an auxiliary electrode each including a light absorbing layer on a substrate;
forming an organic common layer on the pixel electrode and the auxiliary electrode;
locating a first optical mask below the substrate, the first optical mask including a light transmitting portion corresponding to the auxiliary electrode and a non-light transmitting portion corresponding to the pixel electrode; and
removing a portion of the organic common layer positioned on the auxiliary electrode by irradiating light through the first optical mask.

11. The method for manufacturing an organic light emitting diode display of claim 10, wherein:
the forming of the pixel electrode and the auxiliary electrode includes light exposing through a second optical mask.

12. The method for manufacturing an organic light emitting diode display of claim 11, wherein:
the forming of the pixel electrode and the auxiliary electrode includes sequentially depositing a lower layer, a light absorbing layer, a reflective layer, and an upper layer on the substrate and then patterning the deposited layers by using the second optical mask.

13. The method for manufacturing an organic light emitting diode display of claim 11, wherein:
the forming of the pixel electrode and the auxiliary electrode includes sequentially depositing a light absorbing layer, a lower layer, a reflective layer, and an upper layer on the substrate and then patterning the deposited layers by using the second optical mask.

14. The method for manufacturing an organic light emitting diode display of claim 10, wherein:
the light absorbing layer includes at least one metal including molybdenum (Mo), chromium (Cr), tungsten (W), and nickel (Ni).

15. A method for manufacturing an organic light emitting diode display, the method comprising:
forming a pixel electrode, and an auxiliary electrode including a light absorbing layer on a substrate;
forming an organic common layer on the pixel electrode and the auxiliary electrode; and
removing a portion of the organic common layer positioned on the auxiliary electrode by irradiating light to the auxiliary electrode.

16. The method for manufacturing an organic light emitting diode display of claim 15, wherein:
the forming of the pixel electrode and the auxiliary electrode includes light exposing using two or more optical masks.

17. The method for manufacturing an organic light emitting diode display of claim 16, wherein:
the forming of the pixel electrode and the auxiliary electrode includes
sequentially depositing and patterning a lower layer, a reflective layer, and an upper layer on the substrate to form the pixel electrode and a part of the auxiliary electrode, and
depositing and patterning a light absorbing layer on the part of the auxiliary electrode to form the auxiliary electrode.

18. The method for manufacturing an organic light emitting diode display of claim 17, wherein:
the removing of the portion of the organic common layer positioned on the auxiliary electrode includes irradiating light from a side above the substrate.

19. The method for manufacturing an organic light emitting diode display of claim 16, wherein:
the forming of the pixel electrode and the auxiliary electrode includes
depositing and patterning a light absorbing layer on the substrate to forming a part of the auxiliary electrode, and
sequentially depositing and patterning a lower layer, a reflective layer, and an upper layer on the substrate and the light absorbing layer to form the pixel electrode and the auxiliary electrode.

20. The method for manufacturing an organic light emitting diode display of claim 19, wherein:
the removing of the portion of the organic common layer positioned on the auxiliary electrode includes irradiating light from a side below the substrate
